(19) United States
(12) Patent Application Publication
(10) Pub. No.: US 2020/0150196 A1
(43) Pub. Date: May 14, 2020

(54) COMPACT HANLE EFFECT MAGNETOMETER

(71) Applicant: COMMISSARIAT À L'ÉNERGIE ATOMIQUE ET AUX ÉNERGIES ALTERNATIVES, Paris (FR)

(72) Inventors: François Beato, Grenoble cedex (FR); Agustin Palacios Laloy, Grenoble cedex (FR)

(21) Appl. No.: 16/675,828

(22) Filed: Nov. 6, 2019

(30) Foreign Application Priority Data
Nov. 8, 2018 (FR) 1860319

(51) Int. Cl. G01R 33/26

(52) U.S. Cl. CPC G01R 33/26

(57) ABSTRACT

A magnetometer that comprises a cell filled with an atomic gas, an optical source and a detector. The source illuminates the cell with a light that has a pump contribution (Fp), that is linearly polarised at least partially and under the effect of which the atoms of the atomic gas undergo an atomic transition, and a probe contribution (Fs), which is linearly polarised and which undergoes variations in polarisation when passing through the cell. The directions of polarisation of the pump contribution and of the probe contribution are collinear orthogonal. The detector takes a differential measurement of the right circular polarisation and of the left circular polarisation of the probe contribution that has passed through the cell.

### CROSS-REFERENCE TO RELATED APPLICATIONS

This application claims priority from French Patent Application No. 1860319 filed on Nov. 8, 2018. The content of this application is incorporated herein by reference in its entirety.

### TECHNICAL FIELD

The field of the invention is that of optical pumping magnetometers, and more particularly that of Hanle effect magnetometers.

### PRIOR ART

Optical pumping magnetometers use atomic gases confined in a cell, typically metastable helium or alkaline gases, as a sensitive element. These magnetometers, which can have different configurations, make it possible to move through the magnetic field by exploiting the three following processes that take place either sequentially or at the same time:

1) The use of sources of polarised light, typically lasers, makes it possible to prepare atomic states that are characterised by a certain orientation or alignment of their spins. This process receives the name “optical pumping” in the field.

2) These atomic states change under the effect of the magnetic field, in particular under the Zeeman effect which corresponds to offsets of the energy levels according to the magnetic field to which the atoms are subjected.

3) The optical properties of the atomic medium then undergo modifications that depend on the state of the atoms. It is thus possible through an optical measurement, for example via an optical absorption measurement, to go through the subjected Zeeman offset and to deduce therefrom a measurement of the magnetic field wherein the cell is plunged.

According to the various possible configurations of the existing optical pumping magnetometers, we distinguish a measurement of the module, also called norm, of the magnetic field for scalar magnetometers, or a determination of the various components of the magnetic field at the location of the cell for vector magnetometers.

In order to take a vector measurement of the magnetic field with a large bandwidth, there are two well-known configurations: the first is the so-called “Hanle effect” and the second which receives the name of “parametric resonance magnetometer”. These configurations are described in particular in the article by J. Dupont-Roc, “Détermination par des méthodes optiques des trois composantes d'un champ magnétique trés faible,” Revue de Physique Appliquée, vol. 5, no. 6, pp. 853-864, 1970. They operate at very low exterior magnetic field values, inducing a Zeeman offset that is lower than the rate of relaxation of the Zeeman sublevels of the atom, which for the case of helium sets a limit around 100 nano Tesla, which is 500 times less intense than the Earth's magnetic field.

When a weak static transverse magnetic field is applied to the cell and swept around zero, the atoms are subjected to a precession movement and the number of photons absorbed, coming from the optical pumping laser, undergoes resonant variations (Hanle effect). Similar resonances, called parametric resonances, are observed when a radiofrequency magnetic field is applied. In these conditions, the magnetic moment of each atom undergoes resonant oscillations at multiple frequencies of that of the radiofrequency field. Measuring the amplitude of these oscillations makes it possible to move up to the module of the component of the magnetic field collinear to the radiofrequency field.

The Hanle effect magnetometer has for disadvantages being sensitive to the low-frequency noise of the probe laser and to be based, for a measurement of the state of orientation of the atoms, on at least two optical accesses orthogonal to the measuring cell which makes it bulky and complex to carry out. Such a magnetometer, based on a circular polarisation pumping and a polarmetric measurement via the Faraday effect, is for example described in J. C. Allred, R. N. Lyman, T. W. Kornack, and M. V. Romalis, “High-Sensitivity Atomic Magnetometer Unaffected by Spin-Exchange Relaxation,” Phys. Rev. Lett., vol. 89, no. 13, p. 130801, September 2002.

The parametric resonance magnetometer makes it possible to take measurements of several components of a magnetic field with a single optical access using the radiofrequency field or fields used to carry out the frequency modulation of the parametric resonances. This magnetometer however has the following disadvantages:
Its signal level is degraded due to the presence of the radiofrequency field or fields, the amplitudes of the signals are indeed multiplied by combinations of Bessel functions of the first kind less than 1;
When the magnetometer is arranged with other magnetometers of the same type in order to form a network (for example for the purpose of carrying out magnetic imaging), the radiofrequency fields of each magnetometer which are created by coils around the sensitive element can affect the nearby magnetometers through a residual coupling that can modify in particular the direction of measurement of the latter.

### DISCLOSURE OF THE INVENTION

It is sought in general to have a magnetometer that has an optical configuration that is as simple as possible while still offering a signal-to-noise ratio that is as substantial as possible. This is in particular the case in applications of the magnetometer wherein measuring the magnetic field is used to deduce the position of the field sources (currents or magnetic materials) and wherein a signal-to-noise ratio that is too weak is likely to induce great uncertainties as to the magnitude of these sources or the location thereof.

To this effect, the invention proposes a magnetometer comprising a cell intended to be filled with an atomic gas, an optical source and a detector. The optical source is configured to illuminate the cell with a light that has:
a pump contribution, that is linearly polarised at least partially and under the effect of which the atoms of the atomic gas undergo an atomic transition,
a probe contribution, which is linearly polarised and which undergoes variations in polarisation when passing through the cell,
the directions of polarisation of the pump contribution and of the probe contribution being collinear or orthogonal.

The detector comprises a polarisation analyser configured to take a differential measurement of the right circular polarisation and of the left circular polarisation of the probe contribution that has passed through the cell.

Certain preferred but not limiting aspects of this magnetometer are as follows:
the optical source is configured to emit in the direction of the cell a pump beam forming the pump contribution and a probe beam forming the probe contribution;
the directions of propagation of the pump and probe beams are collinear;
the pump and probe beams have an overlapping zone on the cell;
the pump beam is tuned in wavelength at the centre of a first atomic line and the probe beam is tuned in wavelength in such a way as to be offset from the centre of a second atomic line that is different from the first atomic line by being for example tuned to the maximum of the imaginary portion of the Voigt profile of the second atomic line;
it further comprises an optical spectral filtering element of the pump beam that has passed through the cell inserted between the cell and the detector;
the pump beam is tuned in wavelength at the centre of a first atomic line and the probe beam is tuned in wavelength in such a way as to be offset from the centre of the first atomic line by being for example tuned in wavelength to the maximum of the imaginary portion of the Voigt profile of the first atomic line;
the optical source is configured to emit in the direction of the cell a beam tuned in wavelength between the centre of a first atomic line and the maximum of the imaginary portion of the Voigt profile of the first atomic line;
the polarisation analyser is configured to carry out a temporal separation of the right and left circular polarisations of the probe contribution that has passed through the cell;
the polarisation analyser is configured to carry out a spatial separation of the right and left circular polarisations of the probe contribution that has passed through the cell;
the polarisation analyser comprises a quarter-wave plate, a polarisation separator able to separate over a first and a second path the right circular polarisation and the left circular polarisation of the probe contribution that has passed through the cell and a photodetector on each one of the first and second paths;
it further comprises a modulator of the probe contribution.

### BRIEF DESCRIPTION OF THE DRAWINGS

Other aspects, purposes, advantages and characteristics of the invention shall appear better when reading the following detailed description of preferred embodiments of the latter, given by way of a non-limiting example, and in reference to the accompanying drawings wherein:

FIG. 1 is a diagram of a magnetometer in accordance with the invention;

FIG. 2 shows the Voigt profile of an atomic transition line of helium-4;

FIG. 3 shows the curve resulting from the differential measurement taken in the invention.

### DETAILED DISCLOSURE OF PARTICULAR EMBODIMENTS

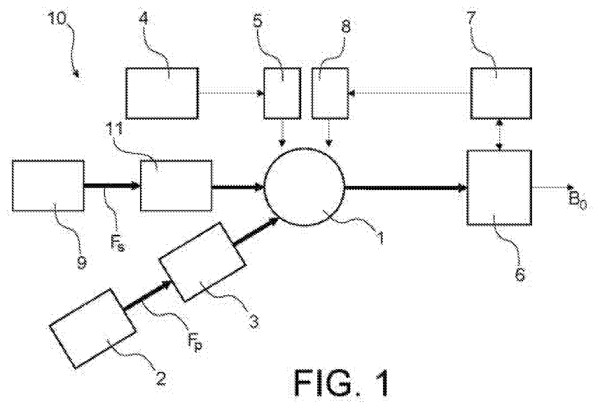

In reference to FIG. 1, the invention relates to an optical pumping vector magnetometer 10 that comprises a cell 1 filled with an atomic gas able to be polarise in alignment, for example helium-4 or an alkaline gas, and which is subjected to an ambient magnetic field B₀. The magnetometer 10 moreover comprises an optical source 2, 3, 9, 11 configured to illuminate the cell and a detector 6 that receives a light that has passed through the cell and delivers a signal bearing information relative to the state of alignment of the atoms of the atomic gas in the cell to an electronic processing that exploits this signal in order to provide a measurement of the ambient field B₀.

In the case where the sensitive element is helium-4, the magnetometer 10 moreover comprises a high-frequency (HF) discharge system, comprising a HF 4 generator and overvoltage coils 5, to bring the atoms of the atomic gas in an energised state where they are able to be subjected to an atomic transition, typically in the metastable state 2³S₁.

The magnetometer can also include a closed loop control system of the magnetometer in order to constantly subject the cell to a zero total magnetic field. The control system comprises a regulator 7 coupled to the electronic processing that injects a current into Helmholtz coils 8 of orthogonal axes that surround the cell 1 in order to generate a magnetic field of compensation Bc such that the sum Bc+B₀ is constantly maintained at zero. Alternatively, the magnetometer can be operated in an open loop, without compensation for the ambient field.

Within the framework of the invention, the optical source is configured to illuminate the cell with a light that has both a pump contribution and a probe contribution, with these two contributions having a linear polarisation and collinear or orthogonal polarisation directions.

Under the effect of the pump contribution, the atoms of the atomic gas undergo an atomic transition. The pump contribution can to this effect be tuned in wavelength at the centre of an atomic transition line, for example on the line D₀ at 1083 nm in the case of helium-4, even be slightly offset from such a centre as shall be described in what follows in order to provide both the role of a pump and a role of a probe. The term wavelength tuned at the centre of a line typically means that the wavelength is separated from the centre of the line by at most half of the width at mid-height of the line, i.e. at ±0.85 Ghz from the centre for the line D₀ of helium.

The probe contribution undergoes variations in polarisation during the passing through of the cell. It can to this effect be tuned in wavelength to the maximum of the imaginary portion of the Voigt profile of an atomic transition line (which may or may not be the same as that used for pumping) or be sufficiently separated from the centre of the atomic line in order to not also pump the atoms, by being for this typically separated from the centre of the line by at least one quarter of the width at mid-height of the line.

When the line used for the probing is different from that used for the pumping, the sensor and probe contributions are then tuned on two relatively separated wavelengths. In such a case, an optical spectral filtering element of the light can be inserted between the cell and the detector in order to suppress the pump contribution so that it does not contribute any noise on the detection.

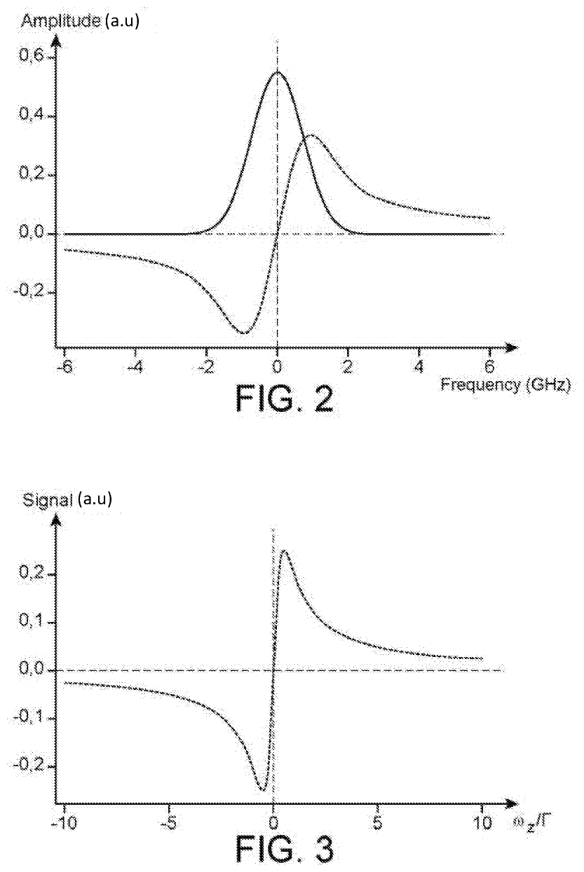

FIG. 2 shows the Voigt profile of the atomic transition line D₀ of helium-4 and more particularly the real portion of this profile as a solid line and the imaginary portion of this profile as a dotted line. The real portion is representative of the pumping intensity while the imaginary portion is representative of the intensity of the probe signal. In this figure, the line is centred on the zero frequency and the maximum of the imaginary portion is at 943.5 MHz from the centre of the line.

In a possible embodiment, which is the one shown in FIG. 1, the optical source is configured to emit in the direction of the cell a pump beam Fp forming the pump contribution and a probe beam Fs forming the probe contribution. The cell is thus illuminated by an optical source that comprises a pumping element 2 able to emit in the direction of the cell 1 the pump beam Fp and a probing element 9 able to emit in the direction of the cell 1 the probe beam Fs. These elements 2, 9 can be lasers, for example semi-conducting diodes.

The pump beam Fp is polarised by means of a polarisation device 3 inserted between the pumping element 2 and the cell 1 or directly integrated into the pumping element 2. Within the framework of the invention, the pump beam Fp is polarised linearly, at least partially, which induces so-called “aligned” atomic states in the cell 1, the axis of alignment being fixed by the direction of the electric field of the light used for the pumping. In what follows, a reference trihedral xyz is considered with the X axis aligned on the direction of linear polarisation of the pump beam. The term partially polarised beam means a beam which is partially polarised linearly according to the X axis and partially depolarised, with its Stokes parameters being such that S1+S2+S3≤S0 as is presented in chapter 8 of the book “Optics” by Eugene Hecht, Addison Wesley 2002.

The probe beam Fs is polarised linearly by means of a polarisation device 11 inserted between the probing element 9 and the cell 1 or directly integrated into the probing element 9. Its direction of polarisation is according to the X axis (collinear to the direction of polarisation of the pump beam) or according to the Y axis (orthogonal to the direction of polarisation of the pump beam). The probe beam Fs propagates according to the Z axis of the trihedral xyz.

In FIG. 1, the directions of propagation of the pump and probe beams are not collinear but these beams have a slight angular offset such that they have an overlapping zone on the cell. In such a configuration, it is advantageously provided that the pump beam not be incident on the detector. The angular offset is for example at most 4° in such a way that the two beams come as incidence on the cell via the same optical window.

Alternatively, the directions of propagation of the pump and probe beams are collinear in such a way that the magnetometer has only a single optical access.

In another possible embodiment with a single optical access, the optical source is configured to emit in the direction of the cell a single beam polarised linearly, with this beam playing both the role of the pump and of the probe by carrying both the pump contribution and the probe contribution. To do this, this beam is tuned in wavelength between the centre of an atomic line and the maximum of the imaginary portion of the Voigt profile of the atomic line in order create an adequate compromise between effectiveness of the role of the pump and effectiveness of the role of the probe, by being for example at 563.9 MHz from the centre of the line D₀ for helium 4.

According to the invention, the detector 6 comprises a polarisation analyser configured to take a differential measurement of the right circular polarisation σ+ and of the left circular polarisation σ− of the probe contribution that has passed through the cell. The detector 6 thus delivers, as a signal carrying information relative to the state of alignment of the atoms of the atomic gas in the cell, a signal representative of the difference in the intensities of the right and left circular polarisations. This signal depends solely on the component of the magnetic field according to the Z axis and has, as shown in FIG. 3, the shape of a dispersive Lorentzian curve centred in the zero field. In this FIG. 3, ω_{z}/Γ corresponds to the Larmor pulse of the magnetic field according to the Z axis measured, divided by the term of relaxation of the system.

The polarisation analyser can be configured to carry out a temporal separation of the right and left circular polarisations of the probe contribution that has passed through the cell, for example using a photoelastic modulator. A photodetector thus detects alternatively in time each one of these polarisations.

Alternatively, the polarisation analyser can be configured to carry out a spatial separation of the right and left circular polarisations of the probe contribution that has passed through the cell. To this effect, the polarisation analyser can comprise a quarter-wave plate, a polarisation separator able to separate over a first and a second path the right circular polarisation and the left circular polarisation of the probe contribution that has passed through the cell and a photodetector on each one of the first and second paths.

The magnetometer according to the invention can moreover include a modulator of the probe contribution. The probe contribution can thus be amplitude modulated, in polarisation, even in wavelength in a degraded mode of implementation of an amplitude modulation. The modulation frequency can be sufficiently high, for example of about 30 kHz, in order to overcome the problems of low-frequency noise of the laser that supplies the probe contribution, without however losing signal amplitude. The modulator of the probe contribution can also be a polarisation modulator, for example a photo-acoustic modulator, arranged between the measurement cell and the detector.

The invention makes it possible to provide a magnetometer allowing for the measurement of a component of the ambient magnetic field that has a simplified optical access (a single window) and does not have the loss of the signal-to-noise ratio that is proper to parametric resonance magnetometers. The pump contribution, which is linearly polarised and does not undergo any modification in polarisation, is invisible in the signal coming from the differential measurement.

The operating principle described hereinabove for the measurement of the field according to the Z axis can be enlarged to the measurement of several components of the magnetic field (i.e. measurement according to several axes) with a measured component fixed by the direction of propagation of a dedicated probe contribution. In what follows, the configuration described hereinabove is retained, pumping along the X axis and measuring along the Z axis.

If it is desired to measure the Y axis in addition to the Z axis, a probe contribution that is linearly polarised along the X axis or the Y axis is added and which propagates according to the Y axis.

If it is desired to measure the X axis in addition to the Z axis, a probe contribution is added that propagate according to the X axis. It is then necessary to add a pumping component of the system along a different axis, either by using a single pump contribution that is partially polarised, or by having recourse to another pump contribution.

If it is desired to take a measurement along the three axes, it is necessary to have three probe contributions each propagating in a different direction of space (x, y and z), and an optical pumping that has components according to at least two different axes. A simple way consists in using a total of three beams, where each beam carries out both the role of a pump and of a probe, and of which two of them share the same axis of polarisation.

The invention also relates to a method for measuring a magnetic field using the magnetometer such as described hereinabove. This method in particular comprises:
the illuminating, by the optical source, of the cell with a light that has:
   a pump contribution, that is linearly polarised at least partially and under the effect of which the atoms of the atomic gas undergo an atomic transition,
   a probe contribution, which is linearly polarised and which undergoes variations in polarisation when passing through the cell,
   the directions of polarisation of the pump contribution and of the probe contribution being collinear or orthogonal; and
the taking by means of the detector of a differential measurement of the right circular polarisation and of the left circular polarisation of the probe contribution that has passed through the cell.

1. A magnetometer comprising a cell intended to be filled with an atomic gas, an optical source and a detector, wherein the optical source is configured to illuminate the cell with a light that has:
a pump contribution, that is linearly polarised at least partially and under the effect of which the atoms of the atomic gas undergo an atomic transition,
a probe contribution, which is linearly polarised and which undergoes variations in polarisation when passing through the cell,
the directions of polarisation of the pump contribution and of the probe contribution being collinear or orthogonal,
and wherein the detector comprises a polarisation analyser configured to take a differential measurement of a right circular polarisation and of a left circular polarisation of the probe contribution that has passed through the cell.

2. The magnetometer according to claim 1, wherein the optical source is configured to emit in the direction of the cell a pump beam forming the pump contribution and a probe beam forming the probe contribution.

3. The magnetometer according to claim 2, wherein the directions of propagation of the pump and probe beams are collinear.

4. The magnetometer according to claim 2, wherein the pump and probe beams have an overlapping zone on the cell.

5. The magnetometer according to claim 2, wherein the probe beam is tuned in wavelength at a centre of a first atomic line and the probe beam is tuned in wavelength in such a way as to be offset from a centre of a second atomic line that is different from the first atomic line.

6. The magnetometer according to claim 5, further comprising an optical spectral filtering element of the pump beam that has passed through the cell inserted between the cell and the detector.

7. The magnetometer according to claim 2, wherein the probe beam is tuned in wavelength at a centre of a first atomic line and the probe beam is tuned in wavelength in such a way as to be offset from the centre of the first atomic line.

8. The magnetometer according to claim 1, wherein the optical source is configured to emit in the direction of the cell a beam tuned in wavelength between a centre of a first atomic line and a maximum of an imaginary portion of a Voigt profile of the first atomic line.

9. The magnetometer according to claim 1, wherein the polarisation analyser is configured to carry out a temporal separation of the right and left circular polarisations of the probe contribution that has passed through the cell.

10. The magnetometer according to claim 1, wherein the polarisation analyser is configured to carry out a spatial separation of the right and left circular polarisations of the probe contribution that has passed through the cell.

11. The magnetometer according to claim 10, wherein the polarisation analyser comprises a quarter-wave plate, a polarisation separator able to separate over a first and a second paths the right circular polarisation and the left circular polarisation of the probe contribution that has passed through the cell and a photodetector on each one of the first and second paths.

12. The magnetometer according to claim 1, further comprising a modulator of the probe contribution.

13. A method for measuring a magnetic field using a vector magnetometer comprising a cell filled with an atomic gas, an optical source and a detector, comprising the steps of:
illuminating, by the optical source, the cell with a light that has:
a pump contribution, that is linearly polarised at least partially and under the effect of which the atoms of the atomic gas undergo an atomic transition,
a probe contribution, which is linearly polarised and which undergoes variations in polarisation when passing through the cell,
the directions of polarisation of the pump contribution and of the probe contribution being collinear or orthogonal; and
taking by the detector a differential measurement of a right circular polarisation and of a left circular polarisation of the probe contribution that has passed through the cell.
